(19) United States
(12) Patent Application Publication
(10) Pub. No.: US 2026/0026122 A1
(43) Pub. Date: Jan. 22, 2026

(54) OPTOELECTRONIC DEVICE WITH IMPROVED LIGHT EXTRACTION

(71) Applicant: COMMISSARIAT A L'ENERGIE ATOMIQUE ET AUX ENERGIES ALTERNATIVES, Paris (FR)

(72) Inventors: Jérémy BILDE, Grenoble Cedex 09 (FR); Adrien GASSE, Grenoble Cedex 09 (FR); Dominique NOGUET, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/273,649

(22) Filed: Jul. 18, 2025

(30) Foreign Application Priority Data
Jul. 19, 2024 (FR) FR2407931

(51) Int. Cl. H10F 39/00; H10H 29/01; H10H 29/80

(52) U.S. Cl. CPC H10F 39/8067; H10F 39/024; H10H 29/034; H10H 29/8421

(57) ABSTRACT

A method for manufacturing an optoelectronic device. The method first comprises the provision of a stack comprising a substrate, the upper face of which extends along a longitudinal plane, a first diode and a second diode separated in pairs by a trench. Then, in the trench, a mirror is formed, having a first flank and a second flank oriented respectively facing the first diode and the second diode, each forming a reflection interface for light emitted or received by the diodes, such that the reflection interfaces each form a reflection angle with the longitudinal plane, measured in the mirror, less than 89°.

### TECHNICAL FIELD

The present invention relates to the field of microelectronic and optoelectronic technologies, in particular, the manufacture of light-emitting or light-receiving diode arrays, such as LEDs, and quite specifically, micro-LEDs. It has a particularly advantageous, but non-limiting application, in micro-LED-based display systems, or optical communication systems.

### PRIOR ART

During the manufacture of a diode, and quite specifically, of a microdiode, it is common to form a mirror on its side walls. Such a mirror has two main functions: avoiding the optical crosstalk phenomenon between the LEDs when they are arrayed and increasing the extraction or the detection of light emitted or received by the LED.

A known method for manufacturing high-density LED arrays and for proceeding with the transfer of a substrate epitaxially grown on a support substrate, then for singling out the LEDs by forming trenches in the epitaxially grown substrate. The mirrors bordering the LEDs are thus typically obtained by filling the trenches between the LEDs with a suitable material.

During this process, the trenches are typically produced by an anisotropic plasma etching, in order to achieve LEDs having flanks which are almost perpendicular to the support substrate. However, it has been noted in practice, that after such an etching, the flanks of the LEDs are not perpendicular to the support substrate, as hoped, but have an inclination giving the LEDs a shape flared towards the carrier substrate, as is highlighted by the view reproduced in FIG. 1A. By subsequently depositing a reflective material in the trenches (FIG. 1B), the mirror will be inclined by being oriented facing the carrier substrate (reflection angle α_{refl}′) and will therefore have the effect, in the case of an emitting diode, of redirecting light emitted by the LED towards the carrier substrate. This situation is damaging for the extraction of light through the upper face of the emitting LED. In the case of a receiving diode, this decreases the zone for receiving light, which is damaging for the detection efficiency.

In addition, this etching method tends to reduce the emitting surface or the receiving surface of the LED, i.e. in this case, the surface area of its upper face, which also minimises the light intensity emitted or the detection of light.

Another approach consists of the formation of mirrors between the LEDs, not against their side walls, but on an element located between two adjacent LEDs. Such a method is, in particular, described in document US2021328116 A1. This approach however requires a significant spacing between the adjacent LEDs and therefore does not enable the production of micro-LED arrays having a high density.

There is therefore a need to improve the light extraction or the receiving of light within a micro-LED array. Preferably, this improvement would be obtained without having to concede a significant reduction of the density of the array or an increase of the optical crosstalk.

### SUMMARY

To achieve this aim, a first aspect of the invention relates to a method for manufacturing an optoelectronic device comprising the following steps:
providing a stack comprising:
   i. a substrate having an upper face extending mainly into a plane called longitudinal plane,
   ii. a photoemitting or photoreceptive diode array disposed on the upper face of the substrate, at least one first diode and one second diode of the array are separated by a trench,
forming, in the trench, a mirror with the basis of a first metal material, the formation of the mirror comprising a step of depositing the first metal material in the vapour phase,

Advantageously the dimensions of the trench and at least one parameter for depositing the first metal material in the vapour phase are configured, such that the mirror has:
a first flank oriented facing the first diode, forming an interface called first reflection interface for light emitted or received by the first diode,
a second flank oriented facing the second diode, forming an interface called second reflection interface for light emitted or received by the second diode,
such that the first reflection interface and the second reflection interface each form a so-called reflection angle with the longitudinal plane, measured in the mirror, less than 89°, such that the first reflection interface and the second reflection interface move away respectively from the first diode and from the second diode in the longitudinal plane, as they move away from the substrate.

In the case of an emitting diode, the reflection interfaces defined by the flanks of the mirror make it possible to reflect light emitted by the first light-emitting diode and the second light-emitting diode not being directly extracted by their upper faces. The inclination of the reflection interfaces makes it possible to redirect this light to the upper faces, and therefore to facilitate its extraction. The light extraction from the first light-emitting diode and from the second light-emitting diode being largely improved.

In the case of a receiving diode, the reflection interfaces defined by the flanks of the mirror make it possible to reflect, to the active zones of the first diode and of the second diode, the light arriving in the proximity of the diodes, or arriving on the diodes, but not to their respective active zones. The inclination of the reflection interfaces makes it possible to redirect this light to the active zones, and therefore to facilitate its detection. The light detection of the first diode and of the second diode is largely improved.

Furthermore, the reflection of light emitted or received by the first diode in the direction of its flank makes it possible to avoid it interfering with light emitted or received by the other diodes of the array and, in particular, by the second diode (or conversely). The phenomenon of optical crosstalk between the diodes of the array, is thus limited, even removed.

The parameter of the deposition, in particular, is taken from among: the distance between the target (first metal material source) and the stack during the deposition, the pressure of the deposition, the use of a collimation between the target and the stack during the deposition, the deposition of ions, rather than of neutral species.

A second aspect of the invention relates to an optoelectronic device comprising:
a substrate having an upper face extending mainly into the plane called longitudinal plane,
a photoemitting or photoreceptive diode array disposed on the upper face of the substrate, at least one first diode and one second diode of the array being separated by a trench,

Advantageously, the trench comprises a mirror with the basis of a first metal material, the mirror having:
a first flank facing the first diode, forming an interface called first reflection interface for light emitted or received by the first diode,
a second flank facing the second diode forming an interface called second reflection interface for light emitted or received by the second diode,
such that the first reflection interface and the second reflection interface each form a so-called reflection angle with the longitudinal plane, measured in the mirror, less than 89°, such that the first reflection interface and the second reflection interface move away respectively from the first diode and from the second diode in the longitudinal plane, as they move away from the substrate. Preferably, the mirror extending into the entire volume defined between its first flank and its second flank.

The advantages provided by the method according to the invention are applied mutatis mutandis to the device according to the invention, and conversely.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIG. 1A represents a view of a diode obtained by anisotropic plasma etching.

FIG. 1B represents a view of a mirror formed between two diodes obtained by anisotropic plasma etching.

FIGS. 2A to 2N illustrate different embodiments of the method according to the invention.

FIGS. 2D, 2E and 2F illustrate the deposition of the dielectric layer non-conformingly on the flanks of the diodes.

FIG. 2G illustrates the deposition of the dielectric layer properly on the flanks of the diodes.

FIGS. 2K and 2M illustrate an embodiment, in which the mirror is electrically insulated from the common electrode surmounting the diodes.

FIGS. 2L and 2N illustrate an embodiment, in which the mirror forms part of the common electrode at the diodes.

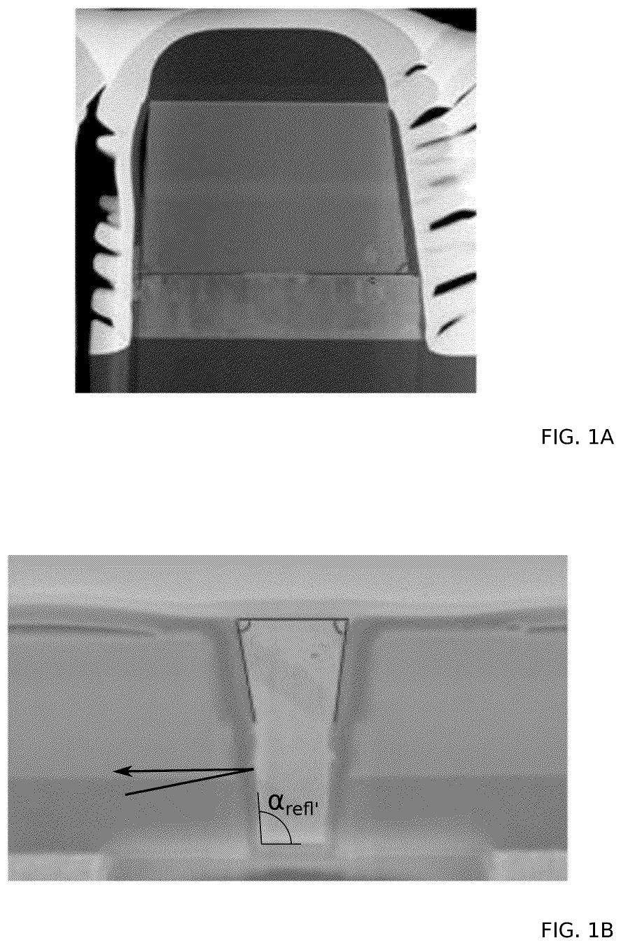

The drawings are given as examples and are not limiting of the invention. They constitute principle schematic representations intended to facilitate the understanding of the invention and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to a preferred embodiment, the first diode and the second diode each have a flank facing the mirror, and the method further comprises the deposition of a dielectric layer with the basis of a first dielectric material and covering said flanks of the first diode and the second diode.

The dielectric layer ensures, in particular, the electrical insulation between the first diode and the second diode. It preferably extends over the entire height of the flanks of the first diode and of the second diode. It moreover preferably extends over the upper face of the diodes, as well as preferably at the bottom of the trench, typically in contact with the upper face of the substrate. It is preferably continuous. In this way, the electrical insulation between the diodes is optimal.

According to an example, the dielectric layer is with the basis of at least one from among the following materials: SiO₂, SiN, SiON, Al₂O₃, AlN. It can also relate to a stack comprising at least one of these materials.

According to a preferred example, the dielectric layer has a first external flank facing the first flank of the mirror and a second external flank facing the second flank of the mirror, and the deposition of the dielectric layer comprises a non-conformal deposition on the flank of the first diode and on the flank of the second diode, the parameters of the non-conformal deposition being adjusted, such that the first external flank and the second external flank of the dielectric layer move away respectively from the first diode and from the second diode in the longitudinal plane as they move away from the substrate. This makes it possible to give the remaining space of the trench, in a cross-section in the plane XZ, a trapezoid shape, which is particularly advantageous for the formation of the inclined flanks of the mirror. Consequently, such a non-conformal deposition of the dielectric layer makes it possible to improve the light extraction and the light capturing. The non-conformity of the deposition, usually considered as a disadvantage, is, in this case, used as an advantage to achieve the desired inclination of the reflection interfaces.

According to another embodiment, the dielectric layer is deposited conformingly on the flank of the first diode and on the flank of the second diode.

According to an example, said parameters of the non-conformal deposition comprise, in particular: a deposition temperature, a deposition pressure, a deposition power and a deposition angle measured between the deposited species flow and the longitudinal plane.

According to an advantageous embodiment, the method further comprises, before the formation of the mirror, the deposition of a perforated mask on each of the diodes, the perforated mask extending partially overhanging the trench. The perforated mask can, for example, be with the basis of a dielectric material, such as SiO₂, SiN, SiON, Al₂O₃, AlN, or also a metal material such as copper, aluminium, gold, silver, nickel, platinum, and titanium or titanium nitride. The perforated mask is deposited on the upper face of the diodes. The perforated mask can also be called shadow mask.

When the dielectric layer is deposited on the upper face of the diodes, the perforated mask is preferably deposited above the dielectric layer. The deposition of the perforated mask therefore preferably occurs after the deposition of the dielectric layer.

The overhang formed by the perforated mask makes it possible to facilitate the formation of the mirror according to the advantageous shape making it possible to improve the light extraction and the light capturing.

According to an advantageous embodiment, the method further comprises, after the formation of the mirror, the formation of a reflective metal coating on the first flank and the second flank of the mirror, the metal coating being with the basis of a second reflective metal material, distinct from the first metal material.

The second metal material preferably has a maximum reflection coefficient located in a range of wavelengths distinct from that in which the maximum reflection coefficient of the first metal material is located.

For example, the first metal material and the second metal material can be chosen, such that one reflects red light particularly well, and the other, blue light. Copper is, for example, an excellent example of first or second metal material to ensure a very good reflection level of red light.

By superposing in this way, two metal layers having maximum reflection coefficients in distinct ranges, a very good reflection level can be ensured over a wide range of wavelengths. It is thus not necessary to make a choice between a good reflection for a reduced range of wavelengths and an average reflection ensured for a wider range of wavelengths.

This variant is particularly advantageous when, on one same initial stack diodes are formed, emitting in distinct colours. It is thus not necessary to adapt the nature of the first metal material to the nature of the neighbouring diodes, which would be complex to implement, and disadvantageous in terms of time and cost.

The light extraction (or the light capturing) is thus improved for the entire diode array, even if this comprises diodes of different natures.

It can moreover be considered to deposit a second reflective metal coating with the basis of a third reflective metal material, distinct from the first metal material and from the second reflective metal material, in order to further expand the range of wavelengths in which a very good reflection level is achieved. The three metal materials selected will advantageously make it possible to reflect for one, red light, for another, blue light, and for the last, green light.

If this variant integrating one or two coating layer(s) is not opted for, aluminium can, for example, be chosen as the first metal material, which constitutes a good compromise and makes it possible to achieve a satisfactory reflection, for all red, green and blue lights.

According to an advantageous embodiment, the method further comprises, after the formation of the mirror, a step of filling the trench with a second dielectric material, preferably identical to the first dielectric material.

According to an advantageous embodiment, the first diode and the second diode each have an upper face, and the method further comprises the formation of a common electrode in contact with the upper faces of the diodes and separated from the mirror by the second dielectric material, the common electrode being with the basis of an electrically conductive material and transparent in a range of wavelengths, in which the first diode and the second diode emit or receive light.

In this example, the common electrode and the mirror are electrically insulated by the second dielectric material. Moreover, before reaching the mirror, light emitted by the diodes is only propagated in dielectric materials, even in one single and same dielectric material. This makes it possible to limit unintentional reflections between the emission of light at the diodes and its reflection against the mirror. These unintentional reflections could indeed be produced along angles less advantageous than that made possible by the mirror. The light extraction is therefore improved. In the case of photoreceptive diodes, a similar observation is made for the light reflected against the mirror and directed towards the diodes: the light detection is improved.

According to an advantageous embodiment, the method further comprises, after the formation of the mirror, a step of filling the trench with an electrically conductive material and transparent in a range of wavelengths, in which the first diode and the second diode emit or receive light.

According to an advantageous embodiment, the first diode and the second diode each have an upper face and the electrically conductive material is also deposited in contact with the upper faces of the diodes, so as to form a continuous layer forming, with the mirror, a common electrode at the diodes.

In this example, the continuous layer of electrically conductive material and the mirror are in electrical continuity and form a common electrode. Including the mirror at the common electrode thus makes it possible to create an electrical path, which is more conductive than that constituted by the deposition of the electrically conductive material. Thus, the response speed of the device is improved.

According to a preferred example, the reflection angle is less than 85°, preferably less than 70°.

According to an example, the first metal material is taken from among the following materials: copper, aluminium, titanium, titanium nitride, gold, silver, nickel and platinum.

According to a preferred example, the first diode and the second diode each have a flank facing the mirror, the device further comprising a dielectric layer with the basis of a first dielectric material and covering said flanks of the first diode and the second diode.

According to a preferred embodiment of the device, the dielectric layer has a first external flank facing the first flank of the mirror and a second external flank facing the second flank of the mirror, the first external flank and the second external flank of the dielectric layer moving away respectively from the first diode and from the second diode in the longitudinal plane as they move away from the substrate.

According to a preferred embodiment, the device further comprises a conductive filling layer extending between the dielectric layer and the mirror, the conductive filling layer being with the basis of an electrically conductive material and transparent in a range of wavelengths, in which the first diode and the second diode emit or receive light.

According to a preferred embodiment, the first diode and the second diode each have an upper face and the conductive filling layer extends until in contact with the upper faces of the diodes, and thus forms a continuous layer forming, with the mirror, a common electrode at the diodes.

According to an example, the dielectric layer is with the basis of at least one from among the following materials: SiO₂, SiN, SiON, AlN, Al₂O₃.

According to an advantageous example, the substrate comprises a plurality of metal vias, each metal via being underlying, along a transverse direction perpendicular to the longitudinal plane, to a distinct diode, and in electrical conduction with said diode.

The present patent application can also be applied to a photoreceptive diode, as it can to a photoemitting diode (as well as to arrays of such diodes). The term “diode” therefore equally means “photoreceptive diode” or “photoemitting diode”. In the present patent application, the terms “photoemitting diode”, “light-emitting diode” and “LED” are used as synonyms. A “diode” can also mean a “microdiode”. A “microdiode” is a diode, the dimensions of which not exceeding 1 mm (1 mm=10⁻³ m).

In the present application, it is meant that a layer is transparent in a given range of wavelengths when this has a transmittance greater than or equal than 70%, preferably greater than 90%, preferably greater than or equal to 95%. In other words, it has an absorbance less than or equal to 30%, preferably less than or equal to 10%, preferably less than or equal to 5% in this range.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers, at least partially, the second layer by being, either directly in contact with it, or by being separated from it by at least one other layer or at least one other element.

A layer can moreover be composed of several sublayers of one same material or of different materials.

By a substrate, a layer, a device, “with the basis of” a material M, means a substrate, a layer, a device comprising this material M only, or this material M and optionally other materials, for example, alloy elements, impurities or doping elements.

By “selective etching with respect to” or “etching having a selectivity with respect to” an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA: B.

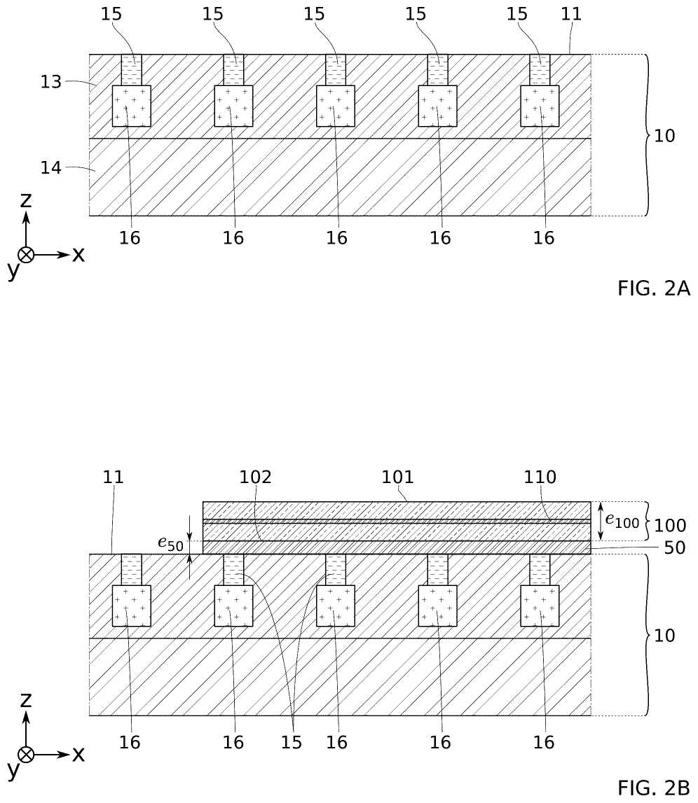

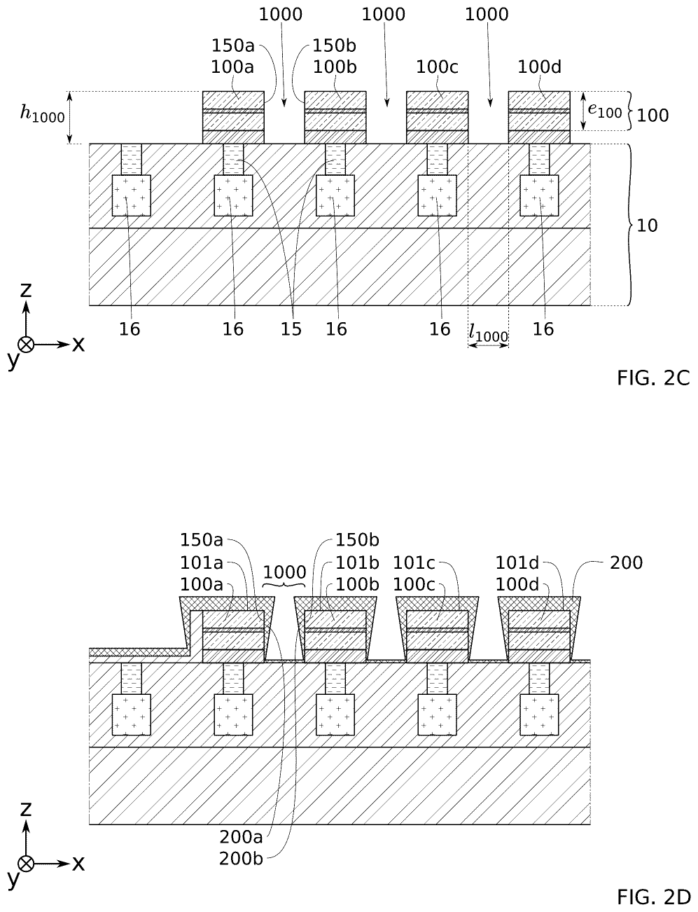

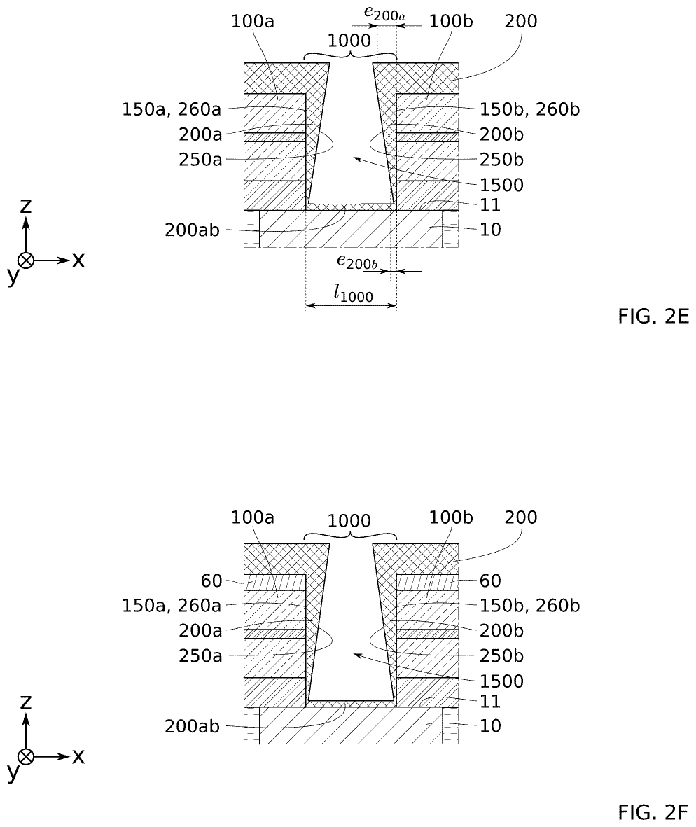

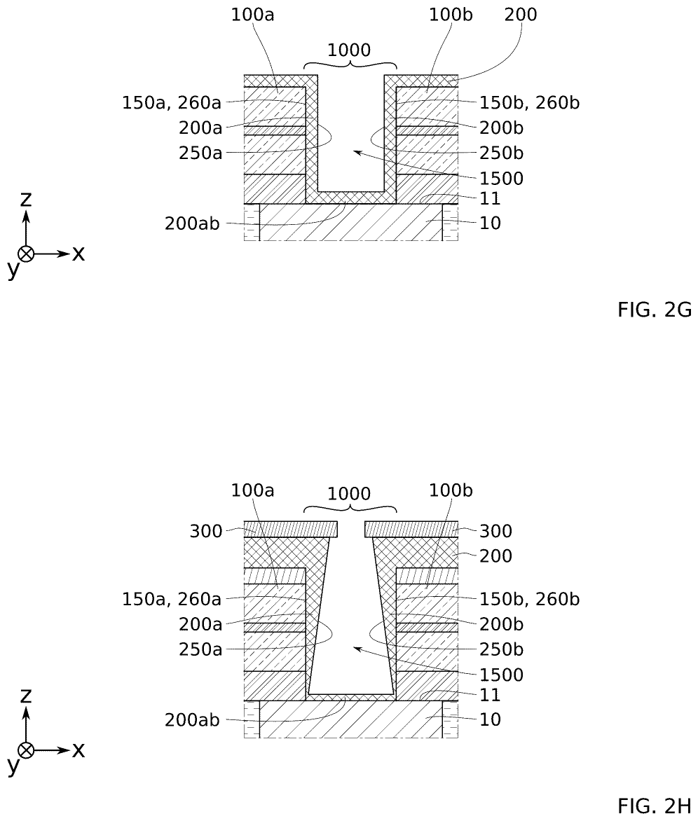

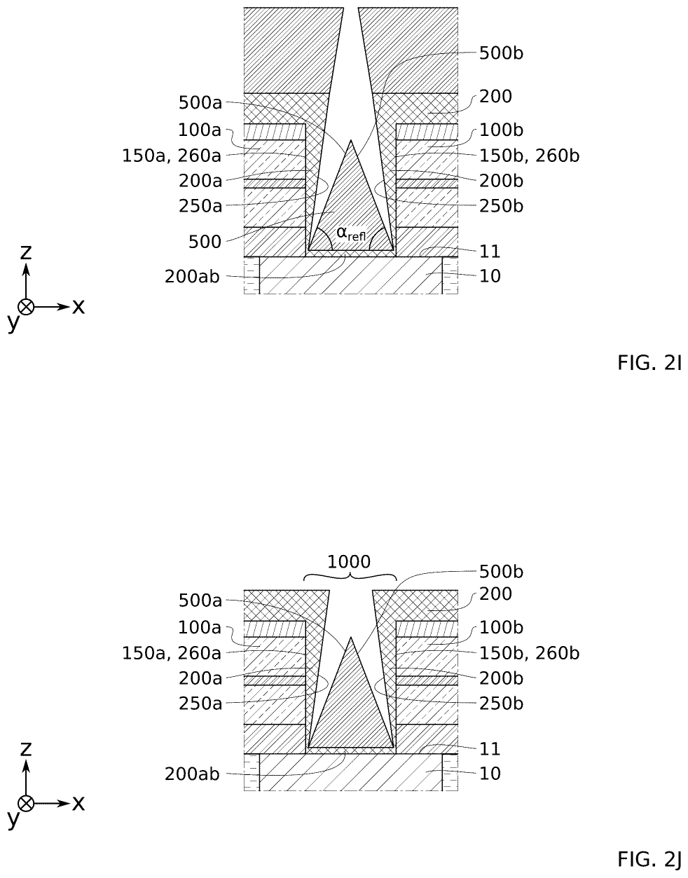

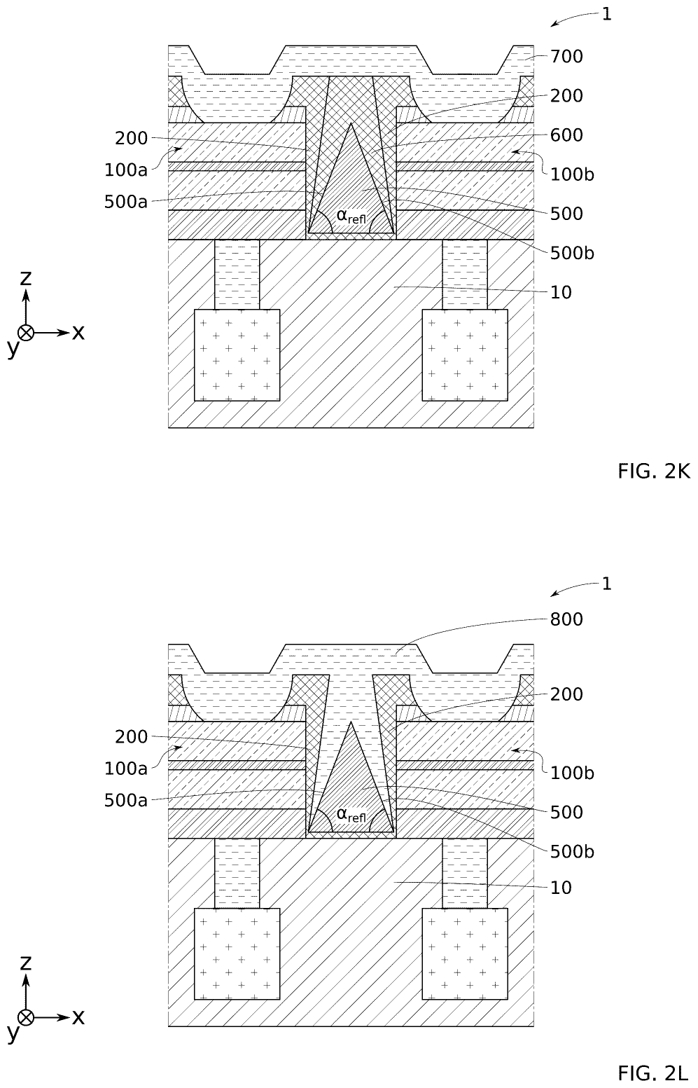

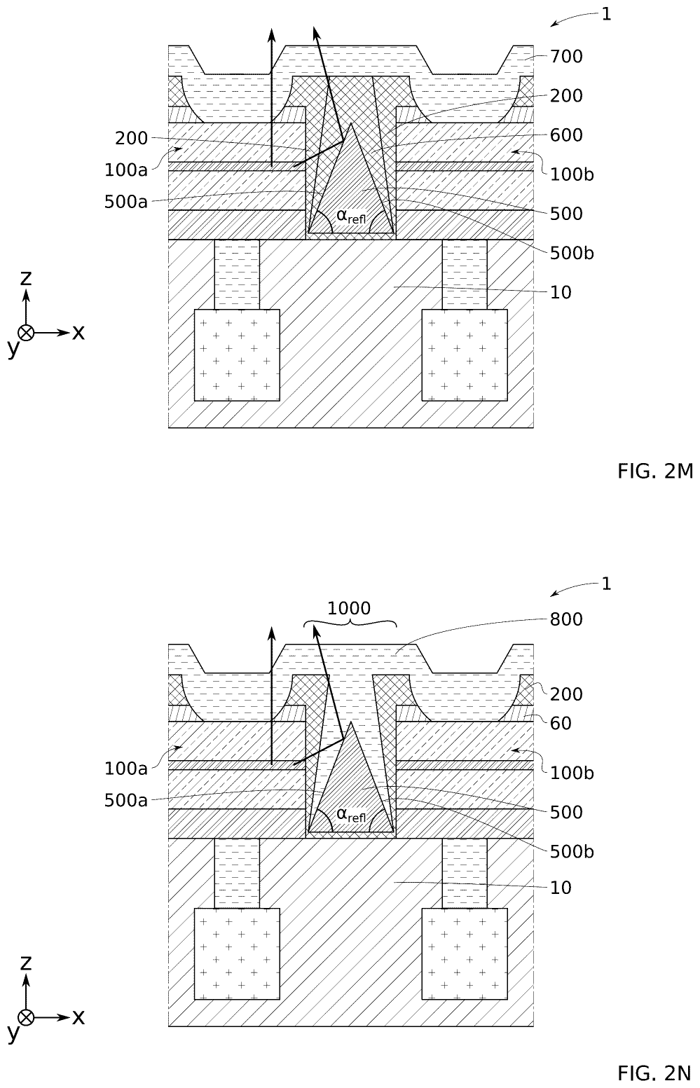

A preferably orthonormal system, comprising the axes X, Y, Z is represented in FIGS. 2A to 2N. The direction Z can be called “stacking direction”.

In the present patent application, preferably thickness will be referred to for a layer, and height will be referred to for a structure or a device. The height is taken perpendicularly to the longitudinal plane XY. The thickness is taken along a direction normal to the main extension plane of the layer. Thus, a layer typically has a thickness along Z, when it extends mainly along the longitudinal plane XY, and a projecting element, for example, an insulation trench, has a height along Z. The relative terms “on”, “under”. “above”, “below”, “underlying” preferably refer to positions taken along the direction Z.

The terms “substantially”, “around”, “about” mean “plus or minus 10%, preferably plus or minus 5%”.

Several embodiments of the method according to the invention will now be described in reference to FIGS. 2A to 2N.

FIG. 2A illustrates the provision of a substrate 10. This is typically a substrate 10 comprising an integrated circuit, being able to be called ASIC (Application Specific Integrated Circuit).

The substrate 10 has an upper face 11 extending mainly into a plane parallel to the longitudinal plane XY.

The substrate 10 can, for example, comprise a flush layer 13 and a support substrate 14. The support substrate 14 can, for example, be a silicon substrate.

The substrate 10, typically the flush layer 13, preferably comprises a plurality of metal vias 15 preferably flush with the upper face 11 of the substrate 10. Each of these metal vias can be in contact with a metal pad 16. The metal vias 15 can, for example, be tungsten-based, and the metal pads can, for example, be copper- or aluminium-based.

FIG. 2B then illustrates the transfer, on the upper face 11 of the substrate 10, of an epitaxially grown substrate 100.

The epitaxially grown substrate 100 has a lower face 102 facing the upper face 11 of the substrate 10 and an upper face 101, opposite its lower face 102. Both extend mainly into one of the planes parallel to the longitudinal plane XY. The epitaxially grown substrate 100 has, along the stacking direction Z, a thickness e₁₀₀. Typically, e₁₀₀ is between 100 nm and 10 μm.

The epitaxially grown substrate 100 is with the basis of a semiconductor material. The epitaxially grown substrate 100 comprises an active region 110. This active region 110 is the location of radiative recombinations of electron-hole pairs making it possible to emit (photoemitter) or absorb (photoreceiver) a light radiation. The active region 131 typically comprises a plurality of quantum wells, for example, formed by GaN-, InN-, InGaN-, AlGaN-, AlN-, AlInGaN-, GaP-, AlGaP-, AlInGaP-, AlGaAs-, GaAs-, InGaAs-, AlInAs-based emissive layers, or a combination of several of these materials.

In order to guarantee the good performance of the epitaxially grown substrate 100 with the substrate 10, the transfer of the epitaxially grown substrate 100 can be done by bonding through an adhesion layer 50 extending between the upper face 11 of the substrate and the lower face 102 of the epitaxially grown substrate 100. The adhesion layer 50 has a thickness e₅₀ along the stacking direction Z.

As illustrated by the passage from FIG. 2B to FIG. 2C, then a lithography and etching step is proceeded with, making it possible to single out a plurality of islands from the active layer 100. For simplification, the flared shape given to the islands by this etching step is not illustrated in FIG. 2C and in the following figures. Each of these islands forms a diode 100a, 100b. 100c. 100d. Each diode 100a, 100b, 100c, 100d comprises a part of the active region 110 of the epitaxially grown substrate 100. The assembly of the diodes 100a, 100b, 100c, 100d is called diode array 100a, 100b, 100c, 100d.

The singling out of the diodes 100a, 100b, 100c, 100d passes through the formation of trenches 1000 within the epitaxially grown substrate 100. Each of these trenches 1000 passes through the epitaxially grown substrate 100 over its entire thickness e₁₀₀. If an adhesion layer 50 is located between the substrate 10 and the epitaxially grown substrate 100, the trenches 1000 preferably also pass through the adhesion layer 50 over its entire thickness e₅₀. If the adhesion layer 50 is not metal, this precaution is however not necessary.

Two adjacent diodes (for example, the diodes referenced 100a and 100b in the figures) are separated by a trench 1000. If a first diode 100a and a second diode 100b adjacent to one another are considered, the trench 1000 separating them extends at least between one flank 150a of the first diode 100a and a flank 150b of the second diode 100b. These flanks 150a, 150b are located facing one another. In the same way, the other trenches 1000 extend at least between two flanks of two adjacent diodes.

Each trench 1000 has a width l₁₀₀₀, measured between the two flanks 150a, 150b of the two diodes 100a, 100b between which it extends. The width l₁₀₀₀ is illustrated in FIG. 2C. The width l₁₀₀₀ corresponds to the shortest distance between these flanks 150a, 150b. The distance between the flanks 150a, 150b being able to vary along the stacking direction Z, due to the etching effects, it is chosen to measure the width l₁₀₀₀ at the base of the diodes 100a, 100b, i.e. in the plane parallel to the longitudinal plane XY including the diodes 100a, 100b closest to the substrate 10. In the case of flanks 150a, 150b having a curved shape in the longitudinal plane XY (for example, if the diodes 100a, 100b have a circular shape projecting into the longitudinal plane XY), the width l₁₀₀₀ is effective, projecting into the longitudinal plane XY, between one single point of the flank 150a of the first diode 100a and one single point of the flank 150b of the second diode 100b. In the case of flanks 150a. 150b parallel to one another, the width loco is effective over the entire extent of these two flanks 150a, 150b.

Typically, l₁₀₀₀ is less than 3 μm, preferably greater than 500 nm, preferably greater than 750 nm, and typically substantially equal to 1 μm.

Each trench 1000 moreover has a height h₁₀₀₀, measured projecting into a plane parallel to the stacking direction Z. h₁₀₀₀ is preferably greater than 100 nm, and typically less than 10 μm.

A dielectric layer 200 is then advantageously deposited in the trenches 1000 so as to cover the flanks 150a, 150b of the diodes 100a, 100b.

The dielectric layer 200 is deposited, so as to have at least one side portion 200a covering at least partially the flank 150a of the first diode 100a. It is preferably deposited, so as to also have at least one other side portion 200b covering at least partially the flank 150b of the second diode 100b.

The side portions 200a, 200b of the dielectric layer 200 moreover each have an internal flank 260a, 260b located facing the first diode 100a and the second diode 100b respectively. Preferably, the dielectric layer 200 is deposited in contact with the first diode 100a and the second diode 100b. Thus, the side portions 200a, 200b preferably extend preferably from the flank 150a of the first diode 100a and from the flank 150b of the second diode 100b. In this scenario, the internal flanks 260a, 260b of the side portions 200a, 200b of the dielectric layer 200 and the flanks 150a, 150b of the first and second diodes 100a, 100b are therefore combined. The side portions 200a, 200b of the dielectric layer 200 moreover respectively have a first external flank 250a and a second external flank 250b, opposite the internal flanks 260a, 260b.

The dielectric layer 200 is preferably also deposited at the bottom of the trenches 1000, typically in contact with the upper face 11 of the substrate 10 when the trenches 1000 pass entirely through the adhesion layer 50, or when there is no adhesion layer 50. The portion of the dielectric layer 200 formed at the bottom of a trench 1000 is called lower portion 200ab. It has an upper face 201AB extending mainly into a plane parallel to the longitudinal plane XY.

The dielectric layer 200 is moreover advantageously deposited on the upper face 101 of the epitaxially grown substrate 100 which, at this stage of the method, is composed of the upper faces 101a, 101b, 101c, 101d of each of the diodes 100a, 100b, 100c, 100d.

According to a first embodiment illustrated in FIGS. 2D, 2E and 2F, the deposition of this dielectric layer 200 is done non-conformingly.

FIG. 2E is a magnification of FIG. 2D representing a trench 1000 separating a first diode 100a from a second diode 100b. This figure makes it possible to best visualise the way in which the dielectric layer 200 is deposited within a trench 1000. The following figures also concentrate on these two diodes 100a, 100b and the trench 1000 separating them, but it is understood that the different steps of the method can be applied to all of the diodes 100a, 100b, 100c, 100d of the array and to all of the trenches 1000.

In the first embodiment of the dielectric layer 200, the deposition of this is configured such that its external flanks 250a. 250b are inclined with respect to the stacking direction Z.

In order to enable the inclination of the external flanks 250a, 250b, the deposition of the dielectric layer 200 advantageously comprises a non-conformal deposition making it possible to form the side portions 200a, 200b along a shape enabling this inclination.

Fully conventionally, a non-conformal deposition is characterised by the fact that the thickness of the deposited layer is not constant. This thickness, at any point of this layer, is measured perpendicularly at the tangent to the layer or at the underlying pattern to the conform layer. In FIG. 2E, it clearly results that, in this embodiment, the thickness e₂₀₀ₐ of the dielectric layer 200 at the upper face of the diode 100 is greater than the thickness e_{200b} of the dielectric layer 200 at the upper face of the diode 100. e₂₀₀ₐ is typically greater than nm, for example, greater than 30 nm. e₂₀₀ₐ is typically less than 1 μm, for example, less than 300 nm.

Preferably, the non-conformal deposition is performed, such that the external flanks 250a, 250b have a constant gradient. Thus, the thickness e₂₀₀ of the dielectric layer increases continuously in the direction of the opening of the trench 1000.

Such a deposition can be performed by plasma enhanced chemical vapour deposition (PECVD), by physical vapour deposition (PVD), or also by ion beam deposition (IBD). Whatever the method retained, the parameters of this are adjusted, in order to obtain a non-conformal deposition. In particular, the following parameters are adjusted to obtain the non-conformal deposition that is sought: the deposition power, the pressure, the deposition temperature, the deposition angle.

Several methods being able to be used to form the dielectric layer 200 non-conformingly are described below:
CVD in a high-frequency generator (e.g. 13.56 MHz), at a power of 300 W, at a pressure of 2.5 Torr and a temperature of 240° C. for example, with N₂O as an oxidising gas, and preferably with silane (SiH₄) as a precursor gas. The ratio of the oxidising gas over the precursor gas is greater than or equal to 20, preferably greater than or equal to 80.
PVD with an SiO₂ target, an argon (30 sccm) and O₂ (45 sccm) mixture, with a pulsed DC mode generator and a power of 3000 W, a pressure of 0.5 mT and at ambient temperature. The deposition is preferably done along the stacking direction Z.
IBD with an SiO₂ target, krypton ions (4 sccm), a plasma generated with a radiofrequency (RF) generator, a power of 700 W, a pressure of 0.45 mT, a deposition angle—i.e. the angle between the species flow to be deposited and the longitudinal plane XY—of 5°, and at ambient temperature.

According to a second embodiment illustrated in FIG. 2G, the dielectric layer 200 is deposited conformingly.

As is illustrated in FIG. 2F, it is possible to preserve a lithography mask 60, such as a photosensitive resin mask, having served to single out the diodes by formation of the trenches 100 (masking and photolithography steps not illustrated occurring between FIGS. 2B and 2C). The dielectric layer 200 is thus deposited on this mask 60. It is, however, also possible to remove this mask and deposit the dielectric layer 200 directly in contact with the upper face 101a, 101b of the diodes 100a, 100b, as illustrated in FIGS. 2E and 2G, for example.

The dielectric layer 200 is with the basis of a dielectric material. The dielectric material and the thickness of the dielectric layer 200 are chosen, such that the dielectric layer 200 is transparent in the emission or receiving range of the diodes 100a, 100b, 100c, 100d. Emission range is referred to for photoemitting diodes, and receiving range is referred to for photoreceptive diodes. To generally refer to either of these ranges, according to the nature of the diode, range of interest is referred to.

When the dielectric layer 200 is not deposited conformingly and therefore does not have a constant thickness, the transparent character of the dielectric layer 200 will be evaluated in its thickest portions. Typically, the dielectric layer 200 is the thickest in its portions surmounting the diodes 100a, 100b, 100c, 100d and/or at the level farthest away from the substrate 10 of its side portions 200a, 200b.

The dielectric layer 200 can, in particular, be with the basis of one from among SiO₂, SiN, SiON or also alumina. This can also be a stack of several of these materials.

Following the deposition of the dielectric layer 200, the deposition of a perforated mask 300 is advantageously provided on the upper face 101a, 101b of the diodes 100a, 100b. As illustrated in FIG. 2H, projecting into the longitudinal plane XY, this perforated mask 300 extends beyond the upper faces 101a, 101b of the diodes 100a, 100b. It thus extends overhanging the trench 100. It moreover preferably extends, projecting into the longitudinal plane XY, beyond the side portions 200a, 200b of the dielectric layer 200. The perforated mask 300 thus forms an advancement above the trench 1000. It defines, above this trench 1000, a particularly advantageous narrow opening for the formation of the mirror 500, which will be described further.

The stack provided at the start of the method according to the invention can correspond to the stacks illustrated in FIGS. 2D, 2E, 2F, 2G or also 2H.

Following this provision step, a mirror 500 with the basis of a first metal material is formed in the trench 1000. The mirror 500 has the function of reflecting light emitted by the diodes 100a, 100b or reflecting the arriving light towards the device 1 in the direction of the diodes 100a, 100b. The first metal material can, in particular, be chosen from among the following materials: copper, aluminium, gold, silver, nickel, platinum and titanium.

This mirror 500 is deposited by a method for vapour deposition of the first metal material. Once deposited, the mirror 500 has flanks 500a, 500b forming reflection interfaces. The deposition is configured, such that the flanks 500a, 500b of the mirror 500 are inclined with respect to the stacking direction Z. The first flank 500a of the mirror 500, located facing the first diode 100a, and the second flank 500b of the mirror 500, located facing the second diode 100b, each form a reflection angle α_{refl}, measured in the mirror 500. This reflection angle α_{refl} is preferably less than 89°. Advantageously, it is even less than 85° even 70°, which enables a better light extraction (or detection, in the case of photoreceptive diodes).

The following parameters can be adapted to obtain such an inclination of the flanks 500a, 500b of the mirror 500:
The dimensions of the trenches 1000, and in particular, h₁₀₀₀ and l₁₀₀₀.
At least one deposition parameter of the first metal material, such that:
   i. The distance between the first metal material source (target) and the stack provided at the start of the method. Typically, this distance is greater than 10 cm, preferably greater than 50 cm. This makes it possible to remove the species which have a directionality far away from the normal incidence. This is applicable, for example, in a sputtering or evaporation method.
   ii. The deposition of ions rather than neutral species, in order to increase the directionality in normal incidence of the species, thanks to a biasing of the substrate, applicable, for example in a sputtering method.
   iii. The use of a collimator between the target and the stack, in order to filter the species, the angle of incidence of which would be too far away from the normal incidence, applicable, for example, in a sputtering or evaporation method.
   iv. The deposition pressure. Typically, this pressure is less than 0.1 Pascal (Pa), ideally less than 1.0×10⁻⁴ Pa, in order to minimise the diffusion of the species during the path of the target to the stack, applicable, for example, in a sputtering, evaporation or molecular jet epitaxy method.
The dimensions of the side portions 200a, 200b of the dielectric layer 200, in particular, its thickness e₂₀₀ₐ (typically 0.1 to 1 μm) and e_{200b} (typically 0.01 to 0.1 μm) at the upper faces of the diodes 100a, 100b,
The dimensions of the perforated mask 300, if such a mask is deposited.

The result of this deposition step is illustrated in FIG. 2I. As illustrated, during this deposition, the first metal material is also deposited above the diodes 100a, 100b, typically on the dielectric layer 200. These portions are located on the upper faces 101a, 101b of the light-emitting diodes 100a, 100b are then preferably removed during a polishing step (FIG. 2J), for example, by chemical-mechanical polishing (commonly called CMP). This makes it possible to avoid light emitted by the diodes 100A, 100B being reflected in the direction of the substrate 10.

Following the deposition of the mirror 500, it is possible to deposit on this, a metal coating with the basis of a second reflective metal material, distinct from the first metal material. The reflective metal coating can, for example, be deposited conformingly on the flanks 500a, 500b of the mirror 500. The second metal material preferably has a maximum reflection coefficient located in a range of wavelengths distinct from that in which the maximum reflection coefficient of the first metal material is located. The presence of the two distinct metal materials thus makes it possible to ensure the reflection of light in a wider range of wavelengths, than if one single metal material was present.

The formation of the mirror 500 is preferably followed by a step of filling the trench 1000. Two main embodiments detailed below are distinguished.

According to a first embodiment illustrated in FIGS. 2K and 2M, the trench 1000 is filled by an insulating filling layer 600 with the basis of a second dielectric material, which can be identical to the first dielectric material of the layer 200.

Then, if the dielectric layer 200, and optionally a mask 60, have been deposited/preserved on these upper faces 101a, 101b, opens are formed inside, so as to expose at least partially the upper faces 101a, 101b of the diodes 100a. 100b. Then, advantageously, a common electrode 700 is deposited in contact with the upper faces 101a, 101b of the diodes 100a, 100b. This common electrode 700 is continuous and extends, in particular, above the trench 1000 and, in particular, from the mirror 500. The common electrode 700 is with the basis of an electrically conductive material. The latter is preferably transparent in a range of wavelengths, in which the first diode and the second diode emit or receive light.

In this first embodiment, the common electrode 700 and the mirror 500 are electrically insulated by the second dielectric material. According to a variant of this embodiment, the common electrode 700 and the mirror 500 are electrically connected, for example, by a via in the insulating filling layer 600.

Moreover, in this first embodiment, it is not necessary to deposit the dielectric layer 200 on the flanks 150a, 150b of the diodes 100a, 100b, as the electrical insulation between the mirror 500 and the diodes 100a, 100b is ensured anyway by the insulating filling layer 600.

FIG. 2M schematically illustrates the reflection of light emitted by the first diode 100a by the reflection interface formed by the first flank 500a of the mirror in this first embodiment. The inclination along the angle α_{refl} of this interface makes it possible to redirect light, in order to enable its extraction through the upper face 101a of the diode 100a.

According to a second embodiment illustrated in FIGS. 2L and 2N, the volume between the dielectric layer 200 and the mirror 500 is filled by a conductive filling layer 800 with the basis of an electrically conductive material. The conductive filling layer 800 and the mirror 500 are thus in contact. The preferably transparent electrically conductive material in a range of wavelengths, in which the first diode and the second diode emit or receive light. Light will thus pass through it, to be reflected at the flanks 500a, 500b.

According to a particularly advantageous example, the conductive filling layer 800 is also deposited above the diodes 100a, 100b, in contact with their respective upper faces 101a, 101b. If the dielectric layer 200, and optionally a mask 60, have been deposited/preserved on these upper faces 101a, 101b, openings inside are formed beforehand, so as to expose at least partially, the upper faces 101a, 101b of the diodes 100a, 100b. Then, the conductive filling layer 800 is deposited in the trench 1000 and in contact with the upper faces 101a, 101b of the diodes 100a, 100b, and this, continuously. The conductive filling layer 800 and the mirror 500 thus together form a common electrode at the diodes 100a, 100b. The materials being able to be used as a first metal material for the mirror 500 being particularly good electrical conductors, this embodiment makes it possible to decrease the electrical resistance of access of the optoelectronic device.

In this second embodiment, care will be taken to deposit the dielectric layer 200 on the flanks 150a, 150b of the diodes 100a, 100b to ensure the electrical insulation between the mirror 500 and the conductive filling layer 800 on the one hand, and the diodes 100a, 100b on the other hand.

FIG. 2N schematically illustrates the reflection of light emitted by the first diode 100a by the reflection interface formed by the first flank 500a of the mirror in this second embodiment. The inclination along the angle α_{refl} of this interface makes it possible to redirect light, in order to enable its extraction through the upper face 101a of the diode 100a.

In the two embodiments described above, it is then advantageous to deposit an antireflective layer with the basis of a dielectric material above the common electrode 700 or the conductive filling layer 800. The antireflective layer can, for example, be SiO₂-, SiN-, SiON-based, or also be a multilayer of several of these elements. This antireflective layer (not represented in the figures) makes it possible to increase the light extraction. It also makes it possible to protect the electrically conductive material forming the common electrode 700 or the conductive filling layer 800.

Another aspect of the invention relates to an electronic device being able to be obtained by any one of the embodiments of the method according to the invention described above.

This device comprises at least the substrate 10, the first diode 100a and the second diode 100b within the diode array 100a, 100b, 100c, 100d, as well as the mirror 500, such as defined above in reference to the method according to the invention.

FIGS. 2K and 2L illustrate two different embodiments of this device.

Through the different embodiments described above, it clearly appears that the invention proposes an effective solution for improving the light extraction and reducing the optical crosstalk in a micro-LED array.

The invention is not limited to the embodiments described above, and extends to all the embodiments covered by the invention.

1. A method for manufacturing an optoelectronic device, the method comprising:
providing a stack comprising a substrate having an upper face extending mainly into a longitudinal plane, and a photoemitting or photoreceptive diode array disposed on the upper face of the substrate, at least one first diode and one second diode of the array being separated by a trench, and
forming, in the trench, a mirror with the basis of a first metal material, the forming of the mirror comprising depositing the first metal material in the vapour phase,
wherein dimensions of the trench and at least one parameter for depositing the first metal material in the vapour phase are configured, such that the mirror includes:
a first flank oriented facing the first diode, forming a reflection interface for light emitted or received by the first diode, and
a second flank oriented facing the second diode, forming a second reflection interface for light emitted or received by the second diode, and
wherein the first reflection interface and the second reflection interface each form a reflection angle with the longitudinal plane, measured in the mirror, less than 89°, such that the first reflection interface and the second reflection interface move away respectively from the first diode and from the second diode in the longitudinal plane as the first and second reflection interfaces move away from the substrate.

2. The method according to claim 1, wherein the first diode and the second diode each have a flank facing the mirror, and
the method further comprises depositing a dielectric layer with the basis of a first dielectric material and covering said flanks of the first diode and the second diode.

3. The method according to claim 2, wherein the dielectric layer includes a first external flank facing the first flank of the mirror and a second external flank facing the second flank of the mirror, and
wherein the depositing of the dielectric layer further comprises a non-conformal depositing on the flank of the first diode and on the flank of the second diode, the parameters of the non-conformal depositing being adjusted, such that the first external flank and the second external flank of the dielectric layer move away respectively from the first diode and from the second diode in the longitudinal plane as the first and second external flanks move away from the substrate.

4. The method according to claim 3, wherein said parameters of the non-conformal deposition comprise a deposition temperature, a deposition pressure, a deposition power, and a deposition angle measured between a deposited species flow and the longitudinal plane.

5. The method according to claim 1, further comprising, before the forming of the mirror, depositing a perforated mask on each of the diodes, the mask extending partially overhanging the trench.

6. The method according to claim 1, further comprising, after the forming of the mirror, the forming a reflective metal coating on the first flank and the second flank of the mirror, the metal coating being with the basis of a second reflective metal material, distinct from the first metal material.

7. The method according to claim 1, further comprising, after the forming of the mirror, filling the trench with a second dielectric material.

8. The method according to claim 7, wherein the first diode and the second diode each have an upper face, and
the method further comprises forming a common electrode in contact with the upper faces of the diodes and separated from the mirror by the second dielectric material, the common electrode being with the basis of an electrically conductive material and transparent in a range of wavelengths, in which the first diode and the second diode emit or receive light.

9. The method according to claim 2, further comprising, after the forming of the mirror, filling the trench with an electrically conductive material that is transparent in a range of wavelengths in which the first diode and the second diode emit or receive light.

10. The method according to claim 9, wherein the first diode and the second diode each have an upper face, and
wherein the electrically conductive material is further deposited in contact with the upper faces of the diodes, so as to form a continuous layer, forming with the mirror, a common electrode at the diodes.

11. An optoelectronic device, comprising:
a substrate having an upper face extending mainly into a longitudinal plane, and
a photoemitting or photoreceptive diode array disposed on the upper face of the substrate, at least one first diode and one second diode of the array being separated by a trench,
wherein the trench comprises a mirror with the basis of a first metal material, the mirror including:
a first flank facing the first diode, forming a first reflection interface for light emitted or received by the first diode, and
a second flank facing the second diode forming a second reflection interface for light emitted or received by the second diode,
wherein the first reflection interface and the second reflection interface each form a reflection angle with the longitudinal plane, measured in the mirror, less than 89°, such that the first reflection interface and the second reflection interface move away respectively from the first diode and from the second diode in the longitudinal plane as the first and second reflection interfaces move away from the substrate, the mirror extending into an entire volume defined between the first flank and the second flank.

12. Device The device according to claim 11, wherein the reflection angle is less than 85°.

13. The device according to claim 11, wherein the first metal material is one of copper, aluminium, titanium, titanium nitride, gold, silver, nickel, and platinum.

14. The device according to claim 11, wherein the first diode and the second diode each have a flank facing the mirror, and
the device further comprising a dielectric layer with the basis of a first dielectric material and covering said flanks of the first diode and the second diode.

15. The device according to claim 14, wherein the dielectric layer has a first external flank facing the first flank of the mirror and a second external flank facing the second flank of the mirror, the first external flank and the second external flank of the dielectric layer moving away respectively from the first diode and from the second diode in the longitudinal plane as the first and second external flanks move away from the substrate.

16. The device according to claim 14, further comprising a conductive filling layer extending between the dielectric layer and the mirror, the conductive filling layer being with the basis of an electrically conductive material and transparent in a range of wavelengths in which the first diode and the second diode emit or receive light.

17. The device according to claim 16, wherein the first diode and the second diode each have an upper face, and
wherein the conductive filling layer extends until in contact with the upper faces of the diodes, and thus forms a continuous layer forming, with the mirror, a common electrode at the diodes.

18. The device according to claim 14, wherein the dielectric layer is with the basis of at least one from among the following materials: SiO₂, SiN, SiON, AlN, and Al₂O₃.

19. The device according to claim 11, wherein the substrate comprises a plurality of metal vias, each metal via being underlying, along a transverse direction perpendicular at the longitudinal plane, to a distinct diode, and in electrical conduction with said diode.
